(19) United States
(12) Patent Application Publication
(10) Pub. No.: US 2006/0261469 A1
(43) Pub. Date: Nov. 23, 2006

(54) Sealing membrane for thermal interface material

(75) Inventors: Ching-Yu Ni, Hsinchu (TW); Hsin-Yu Pan, Taipei (TW); Tsorng Dih Yuan, Hsinchu (TW)

Correspondence Address: BIRCH, STEWART, KOLASCH & BIRCH, LLP, PO BOX 747, 8110 GATEHOUSE RD, STE 500 EAST, FALLS CHURCH, VA, 22040-0747, US

(73) Assignee: TAIWAN SEMICONDUCTOR MANUFACTURING CO., LTD.

(21) Appl. No.: 11/134,303

(22) Filed: May 23, 2005

(51) Int. Cl. H01L 23/34; H01L 21/50

(52) U.S. Cl. 257/718; 257/719; 438/125; 257/717; 257/E23.08

(57) ABSTRACT

A semiconductor package having a sealing membrane for thermal interface material is provided. In one embodiment, the semiconductor package comprises a semiconductor die, a heat spreader, and a sealed membrane for containing a thermal interface material (TIM) therein, the sealed membrane is located between the die and the heat spreader for transmitting heat generated from the die to the heat spreader.

### BACKGROUND

The present invention relates generally to the field of semiconductor devices and, more particularly, to a semiconductor chip package having a thermal interface material (TIM).

Semiconductor chip packages that comprise a flip chip die, a heat spreader, and a thermal interface material between the back of the die and the heat spreader, are well known. The thermal interface material plays a critical function of transferring heat generated by the die to the heat spreader, which then spreads this heat to other elements such as heat sinks, etc. Heat removal becomes a challenge however, as the die power consumption, die size, and heat density increases with every new generation of microprocessors. Thermal interface materials are used to effectively dissipate heat and reduce thermal resistance of the semiconductor chip packages.

The thermal interface material can be a thermal grease type material or a rigid type material (such as epoxy or solder). The thermal grease type has a thermal conductivity of about 1 to 6 W/mk. Epoxy has a thermal conductivity of about 10 to 25 W/mk while solder has a thermal conductivity of about 25 to 80 W/mk.

In a conventional semiconductor package, the thermal interface material is arranged between the back of the die and the heat spreader. In this arrangement, damage may occur depending of the type of thermal interface material used. For example, thermomechanical stresses may arise due to differences in the coefficients of thermal expansion (CTE) between the heat spreader, the die, and the thermal interface material. These CTE differences are commonly referred to as a “CTE” mismatch.“

The rigid type thermal interface material, such as solder, has a good heat emissive capacity, but is not capable of sufficiently absorbing the thermomechanical stresses between the heat spreader and the die. As a result, cracks may occur in the rigid type thermal interface material itself or in the die.

The preferred thermal interface material in use is the grease type thermal interface material, although it exhibits lower heat emissive capacity. The thermal grease type thermal interface material does a good job of absorbing thermomechanical stresses between the heat spreader and the die. However, greases exhibit degradation of thermal performance during temperature cycling. It is observed that in some packages greases migrate out from between the interfaces under cyclical stresses encountered during temperature cycling. This phenomenon is known as “pump out.”

For these reasons and other reasons that will become apparent upon reading the following detailed description, there is a need for an improved thermal interface material for use in semiconductor chip packages having good heat emissive capacity and improved structure for absorbing thermomechanical stresses.

### SUMMARY

The present invention is directed to a semiconductor package having a sealing membrane for a thermal interface material. In one embodiment, the semiconductor package comprises a semiconductor die, a heat spreader, and a sealed membrane for containing a thermal interface material (TIM) therein, the sealed membrane is located between the die and the heat spreader for transmitting heat generated from the die to the heat spreader.

### BRIEF DESCRIPTION OF THE DRAWINGS

The features, aspects, and advantages of the present invention will become more fully apparent from the following detailed description, appended claims, and accompanying drawings in which:

FIG. 1 shows a sealing membrane where a thermal interface material is injected therein according to aspects of the present disclosure.

FIG. 2 is a cross-sectional view of a semi-finished flip chip ball grid array package having a sealing membrane according to aspects of the present disclosure.

FIG. 3 is a cross-sectional view of a semi-finished flip chip ball grid array package having a plurality of sealing membranes for multiple chip module (MCM) packaging according to aspects of the present invention.

### DETAILED DESCRIPTION

In the following description, numerous specific details are set forth to provide a thorough understanding of the present invention. However, one having an ordinary skill in the art will recognize that the invention can be practiced without these specific details. In some instances, well-known structures and processes have not been described in detail to avoid unnecessarily obscuring the present invention.

Reference will now be made in detail to the present preferred embodiments of the present invention, examples of which are illustrated in the accompanying drawings.

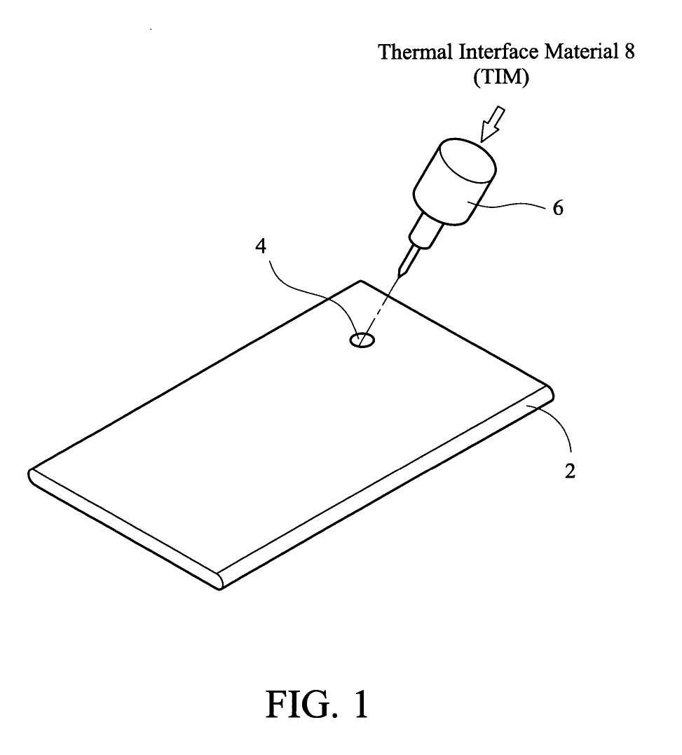

Referring to FIG. 1, a sealing membrane 2 adapted for containing a thermal interface material 8 is shown. The thermal interface material 8 may be injected or delivered to the sealing membrane 2 by way of an injector or pump 6. Injector 6 may be any type injector adapted for delivering thermal interface material 8 to sealing membrane 2 and in one embodiment, may deliver the thermal interface material 8 through an orifice or a series of orifices 4 in sealing membrane 2.

Thermal interface material 8 performs a critical function of transferring heat generated by a die to a heat spreader which then spreads this heat to a heat sink. Thermal interface material 8 may have a modulus of elasticity in the range of about 1 to 500 MPA and be any type of thermally conductive material capable of being delivered to sealing membrane 2. Thermal interface material 8 may be, for example, a thermal grease, gel, polymer, or one of several epoxies.

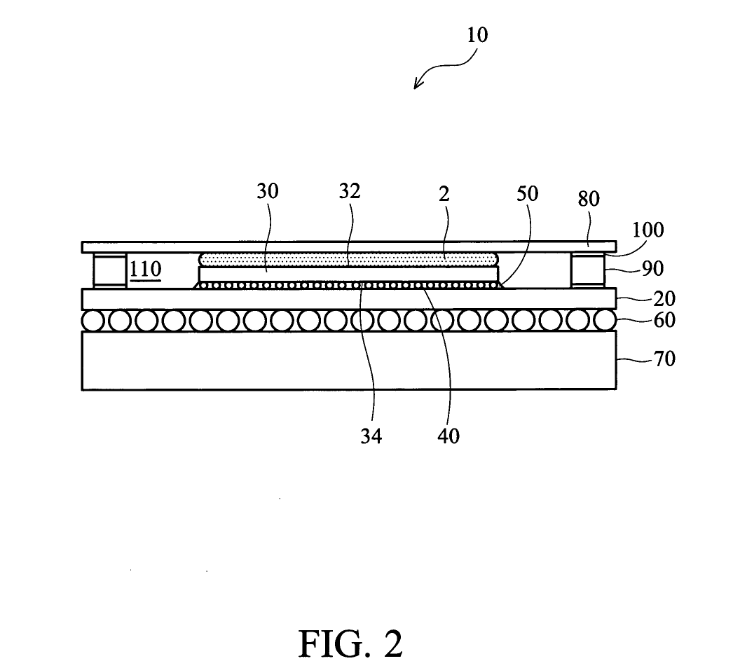

Referring now to FIG. 2, illustrated is a side view diagram of a semi-finished flip chip ball grid array (FCBGA) package 10 having a sealing membrane 2 according to one embodiment of the present invention. FCBGA package 10 includes a semiconductor device 30 such as an integrated circuit chip (hereinafter referred to as chip 30). Chip 30 has an upper surface 32 and a lower surface 34 opposite the upper surface 32. A first set of solder balls 40 (or solder bumps) is connected to contact pads (not shown) on the lower surface 34 of chip 30. The combination of the chip 30 and the solder balls 40 are commonly known as and referred to as a flip chip. Chip 30 is secured to a first substrate 20 underlying chip 30. First substrate 20 may be an inorganic substrate and may include for example, a ceramic containing substrate such as Al₂O₃. Solder balls 40 are attached to contact pads (not shown) on the upper surface of first substrate 20. Although solder balls 40 are employed to couple chip 30 to first substrate 20, any means for coupling the chip to the substrate are within the scope of the present disclosure. FIG. 2 also shows an underfill 50 which may be filled between chip 30 and first substrate 20.

A second set of solder balls 60 may be secured to contact pads (not shown) on the lower surface of first substrate 20. The combination of the first substrate 20 and the second set of solder balls 60 on the lower surface thereof are commonly known as and referred to as a ball grid array. Second set of solder balls 60 may also be secured to contact pads (not shown) on a second substrate 70, which may be a printed wire board (also sometimes called a printed circuit board) or may be a multilayer module known to those skilled in the art.

The FCBGA package 10 may also include a heat spreader 80 and one or more stiffeners 90 for preventing excess warpage of the FCBGA package 10. Heat spreader 80 is mounted on top of chip 30 and counter-balances the forces exerted by the thermal expansion mismatches between at least the chip 30 and the first substrate 20. The heat spreader 80 and the stiffeners 90 may be formed integrally or employed as discrete elements, and may substantially comprise materials having relatively high coefficients of thermal expansion. In one embodiment, the heat spreader 80 comprises copper tungsten, aluminum silicon carbide, aluminum, stainless steel, copper, nickel and/or nickel-plated copper. In one embodiment, the stiffener 90 comprises copper, copper carbon, copper tungsten, aluminum silicon carbide, aluminum, stainless steel, nickel and/or nickel-plated copper. Other materials may be implemented accordingly to meet the design requirements of a particular application and the heat spreader 80 and the stiffener 90 may comprise other materials having high coefficients of thermal expansion as is known to those skilled in the art. However, in one embodiment, heat spreader 80, stiffener 90 may have substantially equal coefficients of thermal expansion, due to substantial similarities of the materials selected for each element.

Further illustrated in FIG. 2, the FCBGA package 10 may include thermal adhesive 100. The thermal adhesive may be disposed between the heat spreader 80 and the stiffeners 90, or between the first substrate 20 and the stiffeners 90, or both. The thermal adhesive 100 may comprise a viscous gel or liquid material, such as thermal grease, silver paste or solder. Thermal adhesive 100 may be applied in the form of a thin layer applied by mechanical layer spreading. Alternatively, thermal adhesive 100 may be applied by capillary action.

In one embodiment, heat spreader 80 has substantially similar dimensions as first substrate 20, although in other embodiments heat spreader 80 may be substantially smaller than first substrate 20. In either case, heat spreader 80 may be sized to substantially cover and enclose first substrate 20 in conjunction with the stiffeners 90. Accordingly, heat spreader 80 and stiffeners 90 may define a cavity 110 within which chip 30 is coupled to the first substrate 20. In one embodiment, the cavity 110 may be substantially filled with a thermo-set epoxy or other underfill material 50 by means known to those skilled in the art.

Also shown in FIG. 2, the FCBGA package 10 includes a sealing membrane 2 disposed between the chip 30 and the heat spreader 80. Sealing membrane 2 containing a thermal interface material 8 transmits the heat generated from chip 30 to heat spreader 80 and protects the FCBGA package 10 from flexural damage. Sealing membrane 2 reduces the warpage of FCBGA package 10 caused by thermal expansion mismatches between at least the chip 30, first substrate 20, and underfill 50. Sealing membrane 2 has substantial flexibility yet maintains dimensional stability and in one embodiment, sealing membrane 2 includes a material, shape, and a thickness that may be adjusted to match the coefficient of thermal expansion of the chip 30, the substrate 20 and the heat spreader 80 as is known to those skilled in the art. By dissipating the stress between the chip 30 and the heat spreader 80, sealing membrane 2 prevents interfacial delaminations at the interfaces of the sealing membrane 2 with the chip 30 and the heat spreader 80. Further, sealing membrane 2 conforms well to surface irregularities upon being disposed on chip 30 and/or the heat spreader 80 and sandwiched therebetween during assembling of the semiconductor package. In one embodiment, sealing membrane may be secured to the upper surface of chip 30 by an adhesive (not shown) such as, for example epoxy. The adhesive may be chosen to match or accommodate the coefficients of thermal expansion of the sealing membrane 2 and chip 30.

Sealing membrane 2 may comprise one or more layers and is so dimensioned as to be insertable through the space between the chip 30 and the heat spreader 80. Sealing membrane 2 comprises a flexible yet high heat transferring material and in one embodiment, sealing membrane 2 comprises silicon rubber. However, one skilled in the art will understand that sealing membrane 2 may comprise of any material having substantial flexibility, high heat emissive capacity yet maintain dimensional stability. In one embodiment, sealing membrane 2 may have a bulk thermal conductivity of 0.1 to 0.3 W/mk and have a flexural modulus less than about 1000 MPa.

Sealing membrane 2 may have a shape comprising of, for example, a rectangle, square, circle, rhombus, ellipse, or polygon but it is understood by those skilled in the art that the shape is dependent on at least the size and shape of the chip 30. The larger the chip is, the larger the sealing membrane size must be to adequately dissipate heat and withstand the package warpage and/or the fabrication process. Other shapes and configurations may be implemented accordingly to meet the design criteria of a particular application. Although FIG. 2 shows that sealing membrane 2 is implemented in a FCBGA package, it is understood by those skilled in the art that sealing membrane 2 may be implemented in any type of semiconductor package according to design criteria.

The thermal interface material for use in the sealing membrane 2 may be, for example, a thermal grease, gel, polymer, or one of several epoxies. In one embodiment, the thermal interface material comprises a conductive material such as aluminum, copper, carbon compound, aluminum compound, silver, or combinations thereof

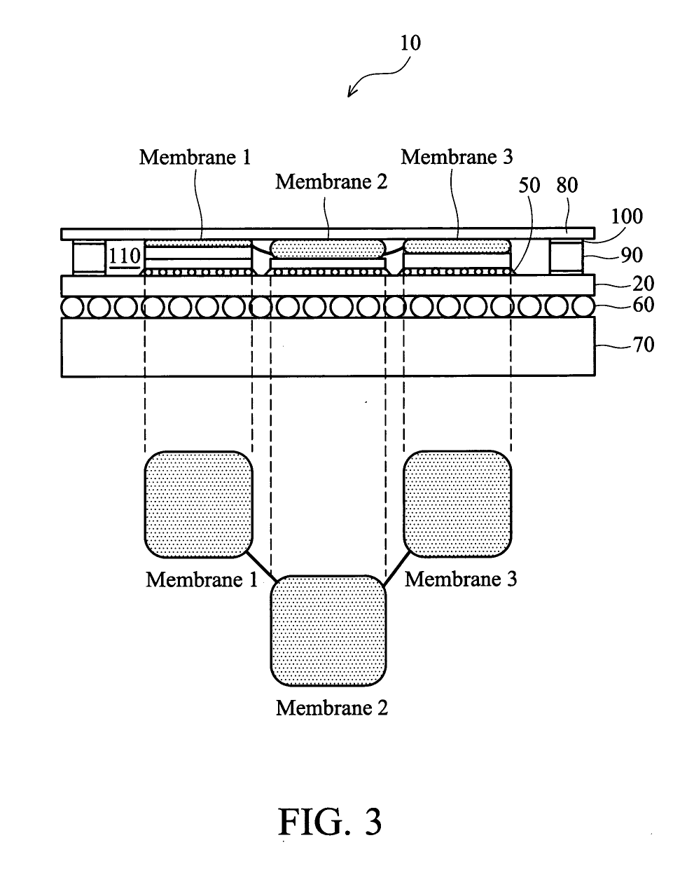

Aspects of the present invention may be used in other semiconductor packaging, such as multiple chip module (MCM). FIG. 3 is a cross-sectional view of a semi-finished flip chip ball grid array package having a plurality of sealing membranes for multiple chip module (MCM) packaging according to aspects of the present invention. The plurality of sealing membranes 1, 2, and 3 as shown in FIG. 3 are connected to each other by a wire, such as for example a plastic wire.

In the preceding detailed description, the present invention is described with reference to specifically exemplary embodiments thereof It will, however, be evident that various modifications, structures, processes, and changes may be made thereto without departing from the broader spirit and scope of the present invention, as set forth in the claims. The specification and drawings are, accordingly, to be regarded as illustrative and not restrictive. It is understood that the present invention is capable of using various other combinations and environments and is capable of changes or modifications within the scope of the inventive concept as expressed herein.

What is claimed is:

1. A semiconductor package comprising:
a semiconductor die;
a heat spreader; and
a sealed membrane for containing a thermal interface material (TIM) therein, the sealed membrane located between the die and the heat spreader for transmitting heat generated from the die to the heat spreader.

2. The semiconductor package of claim 1, further comprising a substrate above which the die, sealed membrane, and the heat spreader are mounted.

3. The semiconductor package of claim 1, further comprising a substrate, and wherein the die is a flip chip mounted above the substrate.

4. The semiconductor package of claim 1, wherein the sealed membrane has substantial flexibility yet maintains dimensional stability.

5. The semiconductor package of claim 2, wherein the sealed membrane includes a material, shape, and a thickness that may be adjusted to match the coefficient of thermal expansion of the die, substrate, and heat spreader.

6. The semiconductor package of claim 1, wherein the sealed membrane is so dimensioned as to be insertable through the space between the die and the heat spreader.

7. The semiconductor package of claim 1, wherein the sealed membrane is placed on the die with an adhesive.

8. The semiconductor package of claim 1, wherein the sealed membrane includes at least one orifice for delivering the thermal interface material thereto.

9. The semiconductor package of claim 1, wherein the sealed membrane has a bulk thermal conductivity of 0.1 to 0.3 W/mk.

10. The semiconductor package of claim 1, wherein the sealed membrane has a flexural modulus less than about 1000 MPA

11. The semiconductor package of claim 1, wherein the sealed membrane comprises silicon rubber.

12. The semiconductor package of claim 1, wherein the thermal interface material is a conductive material selected from the group consisting of aluminum, copper, carbon compound, aluminum compound, silver, or combinations thereof.

13. A method for forming a semiconductor package, comprising:
providing a semiconductor die;
providing a heat spreader;
providing a sealed membrane for containing a thermal interface material therein; and
assembling the sealed membrane between the die and the heat spreader.

14. The method of claim 13 further comprising mounting the die, sealed membrane, and heat spreader above a substrate.

15. The method of claim 13, wherein the die is a flip chip mounted above a substrate.

16. The method of claim 13, wherein the sealed membrane has substantial flexibility yet maintains dimensional stability.

17. The method of claim 13, wherein the sealed membrane is so dimensioned as to be insertable through the space between the die and the heat spreader.

18. The method of claim 13, wherein the sealed membrane is placed on the die with an adhesive.

19. The method of claim 13, wherein the sealed membrane includes at least one orifice for delivering the thermal interface material thereto.

20. The method of claim 13, wherein the sealed membrane comprises silicon rubber.

21. The method of claim 13, wherein the thermal interface material is a conductive material selected from the group consisting of aluminum, copper, carbon compound, aluminum compound, silver, or combinations thereof.

22. A method of dissipating heat from a semiconductor package, comprising:
transferring heat from a semiconductor die in the semiconductor package to a heat spreader with a sealed membrane containing a thermal interface material therein, the sealed membrane located between the die and the heat spreader.

23. The method of claim 22, wherein the sealed membrane has substantial flexibility yet maintains dimensional stability.

24. The method of claim 22, wherein the sealed membrane is so dimensioned as to be insertable through the space between the die and the heat spreader.

25. The method of claim 22, wherein the sealed membrane is placed on the die with an adhesive.

26. The method of claim 22, wherein the sealed membrane includes at least one orifice for delivering the thermal interface material thereto.

27. The method of claim 22, wherein the sealed membrane comprises silicon rubber.

28. The method of claim 22, wherein the thermal interface material is a conductive material selected from the group consisting of aluminum, copper, carbon compound, aluminum compound, silver, or combinations thereof.
